(19) United States
(12) Patent Application Publication
(10) Pub. No.: US 2006/0197133 A1
(43) Pub. Date: Sep. 7, 2006

(54) MIM capacitor including ground shield layer

(75) Inventors: Sung-jae Jung, Seoul (KR); Sang-yoon Jeon, Seoul (KR); Hee-mun Bang, Seoul (KR); Kwang-du Lee, Suwon-si (KR); Heung-bae Lee, Suwon-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 11/360,585

(22) Filed: Feb. 24, 2006

(30) Foreign Application Priority Data
Mar. 2, 2005 (KR) 2005-0017258

(51) Int. Cl. H01L 29/94

(52) U.S. Cl. 257/300

(57) ABSTRACT

An MIM capacitor includes a substrate, a capacitor part having a structure in which a bottom electrode, a dielectric layer and a top electrode are laminated in order, and a ground shield layer formed between the bottom electrode of the capacitor part and the substrate and connected to a predetermined ground terminal. The ground shield layer may be formed of metal or polysilicon, or a layer doped with impurities having a valence of three or five. Also, the ground shield layer has a predetermined patterned structure. Thus, it is possible to minimize power loss due to the substrate.

This application claims priority under 35 U.S.C. § 119 from Korean Patent Application No. 2005-17258, filed on Mar. 2, 2005 in the Korean Intellectual Property Office, the disclosure of which is incorporated herein by reference.

### BACKGROUND OF THE INVENTION

1. Field of the Invention

The present invention relates to an MIM (Metal-Insulator-Metal) capacitor, and more particularly, to an MIM capacitor that can reduce parasitic resistance components using a ground shield layer.

2. Description of the Related Art

With the high integration of a semiconductor device, it has reached a point where desired capacitance could not be obtained by a conventional MIS (Metal-Insulator-Silicon) capacitor. In this respect, an MIM (Metal-Insulator-Metal) capacitor has been newly introduced. The MIM capacitor is a capacitor that uses metal films, such as aluminum, as both electrode plates by interposing a dielectric layer therebetween. The MIM capacitor can be driven even under a low voltage and is used in a highly-integrated semiconductor device because of its high capacitance characteristics in comparison with a cell area.

Generally, the MIM capacitor includes a bottom electrode, a dielectric layer, and a top electrode, which are sequentially deposited on a substrate.

FIG. 1 is a circuit diagram modeled by a conventional MIM capacitor. Referring to FIG. 1, a circuit is modeled in such a manner that a resistor of a predetermined size, an inductor, and a capacitor are connected in series between top and bottom electrodes of the MIM capacitor formed on a substrate. Meanwhile, capacitance Cox of a predetermined size may be formed between the bottom electrode and the substrate. Also, resistance Rsub of the substrate may be included in the circuit.

Thus, signals applied to the top and bottom electrodes may be leaked toward the substrate. For this reason, power loss occurs due to the resistance Rsub. Also, another problem occurs in that noise leaked from other elements on the substrate may be supplied to the MIM capacitor.

### SUMMARY OF THE INVENTION

It is an aspect of the present invention to address the above-mentioned drawbacks and other problems associated with the conventional arrangement. Another aspect of the present invention is to provide an MIM capacitor that minimizes loss of a substrate using a ground shield layer.

According to yet another aspect of the present invention, there is provided an MIM (Metal-Insulator-Metal) capacitor comprising a substrate, a capacitor part having a structure in which a bottom electrode, a dielectric layer and a top electrode are laminated in order, and a ground shield layer formed between the bottom electrode of the capacitor part and the substrate and connected to a predetermined ground terminal.

The MIM capacitor may further comprise an insulating layer deposited on the substrate and positioned between the substrate and the ground shield layer.

The ground shield layer may be made of a predetermined conductive material deposited on the insulating layer.

The ground shield layer may be patterned in a predetermined shape. Also, the ground shield layer may be made of either metal or polysilicon.

Meanwhile, the substrate is a P type silicon semiconductor substrate. In this case, the ground shield layer is made of an N type doped layer formed in one region on the substrate.

### BRIEF DESCRIPTION OF THE DRAWINGS

The above aspects and features of the present invention will be more apparent by describing certain exemplary embodiments of the present invention with reference to the accompanying drawings, in which:

FIG. 1 is a circuit diagram modeled by a conventional MIM capacitor;

FIG. 2 is a vertical sectional view illustrating an MIM capacitor according to one exemplary embodiment of the present invention;

FIGS. 3A to 3C are vertical sectional views illustrating an MIM capacitor according to another exemplary embodiment of the present invention;

FIG. 4 is a plane view illustrating an MIM capacitor according to another exemplary embodiment of the present invention;

FIG. 5 is an example of a horizontal sectional view illustrating a ground shield layer used in the MIM capacitor of FIG. 4; and

FIG. 6 is a graph illustrating variation of power loss depending on the type of a ground shield layer used in an MIM capacitor.

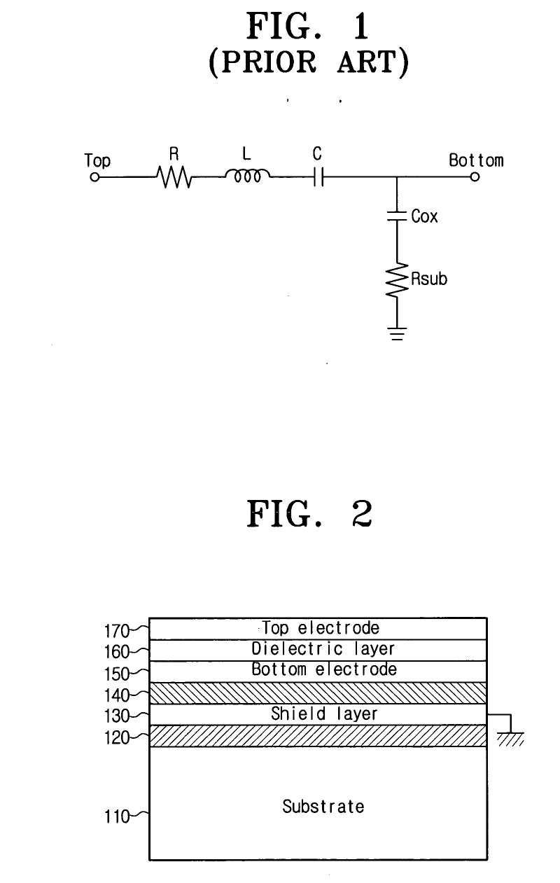

### DETAILED DESCRIPTION OF EXEMPLARY EMBODIMENTS

Certain exemplary embodiments of the present invention will be described in greater detail with reference to the accompanying drawings.

In the following description, same drawing reference numerals are used for the same elements even in different drawings. The matters defined herein are described at a high-level of abstraction to provide a comprehensive yet clear understanding of the invention. It is also to be noted that it will be apparent to those ordinarily skilled in the art that the present invention is not limited to the description of the exemplary embodiments provided herein.

FIG. 2 is a vertical sectional view illustrating an MIM capacitor according to one exemplary embodiment of the present invention. Referring to FIG. 2, the MIM capacitor according to one embodiment of the present invention includes a substrate 110, a first insulating layer 120, a ground shield layer 130, a second insulating layer 140, a bottom electrode 150, a dielectric layer 160, and a top electrode 170.

A silicon substrate is generally used as the substrate 110.

The first insulating layer 120 is made of an insulating material such as SiO₂, and serves to electrically insulate a structure on top of the substrate 110 from the substrate 110.

The ground shield layer 130 is deposited on top of the first insulating layer 120, and is a conductive material layer connected with a predetermined ground terminal. In this case, a resistance value is approximate to “0” when viewed from a side of the bottom electrode 150 toward the substrate. The ground shield layer 130 may be made of a conductive material such as metal and polysilicon. A doped layer of predetermined impurities on the substrate 110 may serve as the ground shield layer 130.

The second insulating layer 140 serves to electrically insulate the ground shield layer 130 from the bottom electrode 150.

The bottom electrode 150, the dielectric layer 160, and the top electrode 170 are sequentially deposited on the second insulating layer 140 to form a capacitor part. The capacitor part has capacitance expressed by Equation (1).

$$C = ɛ \frac{A}{d} \qquad ( 1 )$$

In Equation (1), ε is a dielectric ratio of the dielectric layer 160, A is an area of the top and bottom electrodes, and d is the distance between the top and bottom electrodes.

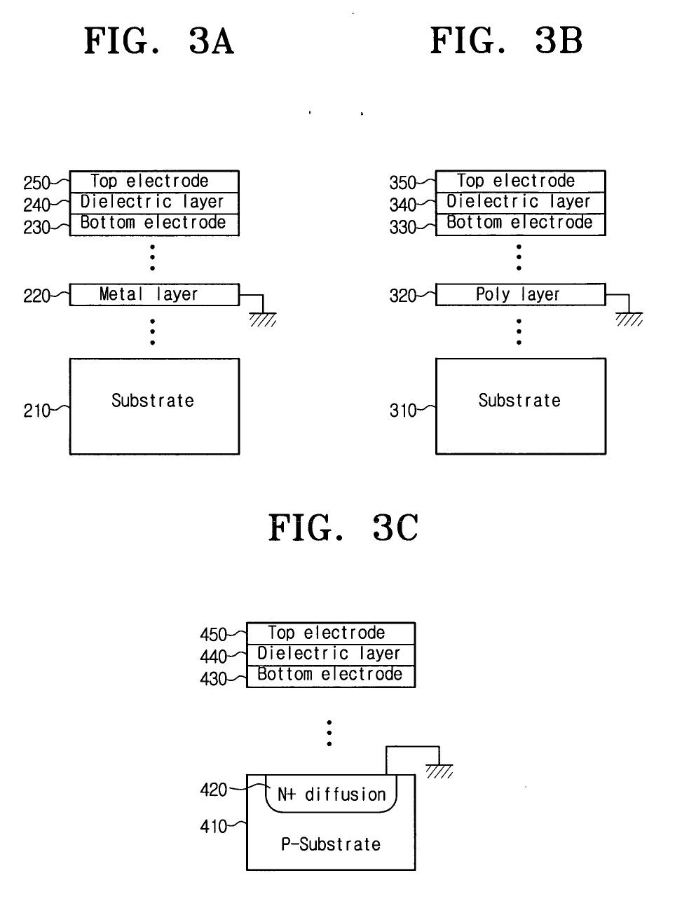

FIG. 3A is a vertical sectional view illustrating an MIM capacitor according to another exemplary embodiment of the present invention. Referring to FIG. 3A, a plurality of material layers are formed between a substrate 210 and a bottom electrode 230. That is, after a plurality of insulating layers and a plurality of metal layers are alternately deposited on the substrate 210, the bottom electrode 230, a dielectric layer 240, and a top electrode 250 are sequentially deposited. The metal layers serve as connecting lines that connect input and output terminals of various elements (not shown) on the substrate 210 with outer terminals. Also, as the insulating layers and the metal layers are deposited, the distance between the bottom electrode 230 and the substrate 210 becomes wide. Therefore, according to the formula 1, the capacitance Cox formed between the bottom electrode 230 and the substrate 210 is reduced.

Meanwhile, one metal layer 220 existing between the bottom electrode 230 and the substrate 210 is connected with a ground terminal to serve as a ground shield layer. Therefore, a resistance value Rsub viewed from the bottom electrode 230 toward the substrate 210 is approximate to “0.” Thus, power loss is reduced.

FIG. 3B is a vertical sectional view illustrating an MIM capacitor according to another exemplary embodiment of the present invention. Referring to FIG. 3B, a poly layer 320 formed between a bottom electrode 330 and a substrate 310 is connected with a ground terminal to serve as a ground shield layer. The poly layer 320 may be made of polysilicon. Meanwhile, since the poly layer 320 has conductivity lower than that of metal layers, the capacitance Cox is lower than that of FIG. 3A but the resistance Rsub is greater than that of FIG. 3A.

FIG. 3C is a vertical sectional view illustrating an MIM capacitor according to another exemplary embodiment of the present invention. Referring to FIG. 3C, impurities having a valence of five, such as P, As, Sb, and Bi, are added to one region on a surface of a P type semiconductor substrate 410 so that an N type doped layer 420 is manufactured. Thus, the N type doped layer 420 is connected with a ground terminal to serve as a ground shield layer. Meanwhile, a plurality of material layers may be formed between the N type doped layer 420 and a bottom electrode 430 as described above. In FIG. 3C, although the N type doped layer 420 formed on the P type substrate 410 is used as the ground shield layer, a P type doped layer may be formed on an N type substrate to serve as the ground shield layer.

In the case where the metal layer 220, the poly layer 320, and the N type doped layer 420 are respectively used as the ground shield layers as shown in FIGS. 3A to 3C, the capacitance Cox and the resistance Rsub are formed as follows.

TABLE 1

| | |
|---|---|
| Cox[fF] | Rsub[Ω] |

| | | |
|---|---|---|
| (a) 20 × 20 metal shield | 6.0 | 23 |
| (b) 20 × 20 poly shield | 4.1 | 55 |
| (c) 20 × 20 N+ diffusion shield | 3.8 | 52 |
| (d) 20 × 20 No shield | 4.0 | 931 |

Table 1 illustrates experimental results in the case where the metal layer, the poly layer and the N type doped layer are respectively used as the ground shield layer having horizontal and vertical lengths in the range of 20 μm, and also the result when no ground shield layer is formed. If no ground shield layer is formed as shown in (d) of Table 1, a considerably high resistance Rsub of 931 Ω is generated. In contrast, if the ground shield layer is formed as shown in (a) to (c) of Table 1, power loss is greatly reduced. Meanwhile, if the metal layer is used as the ground shield layer as shown in (a), the capacitance Cox is increased more than that of the cases (b) and (c), but the resistance Rsub is reduced. Considering this, it is preferable, but not necessary, that the metal layer, the poly layer and the N type doped layer are optionally selected depending on the type of a circuit to be designed, so that the selected layer is used as the ground shield layer.

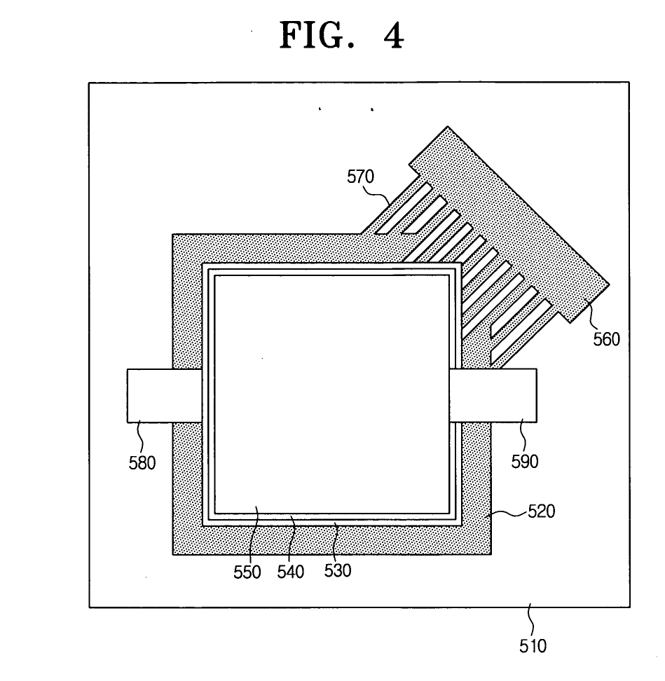

FIG. 4 is a plane view illustrating an MIM capacitor according to another exemplary embodiment of the present invention. Referring to FIG. 4, a ground shield layer 520, a bottom electrode 530, a dielectric layer 540, and a top electrode 550 are sequentially deposited on a substrate 510, so that the MIM capacitor is completed.

Meanwhile, a first electrode 560 to be connected with an outer ground terminal is also formed on the substrate 510. The first electrode 560 is connected with the ground shield layer 520 through a connector 570.

The ground shield layer 520, the connector 570, and the first electrode 560 may be manufactured together by depositing one conductive layer on the substrate 510 and then patterning it.

Meanwhile, the bottom electrode 530 and the top electrode 550 can be connected to the outer terminal through a second electrode 580 and a third electrode 590, respectively.

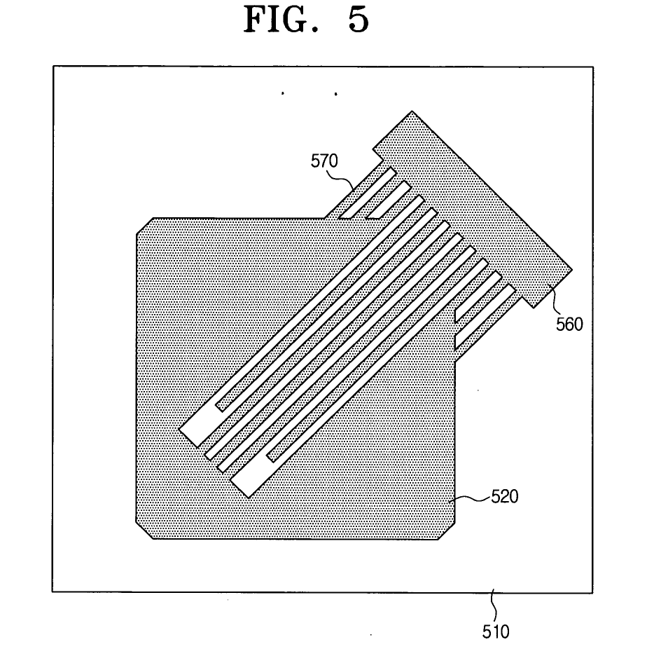

FIG. 5 is a horizontal sectional view illustrating the ground shield layer 520 used in the MIM capacitor of FIG. 4. Referring to FIG. 5, the ground shield layer 520 has a predetermined patterning structure and not a film structure. In this case, since the ground shield layer 520 has a decreased area, the capacitance Cox is reduced. The area of the ground shield layer 520 is controlled to control the capacitance Cox and the resistance Rsub.

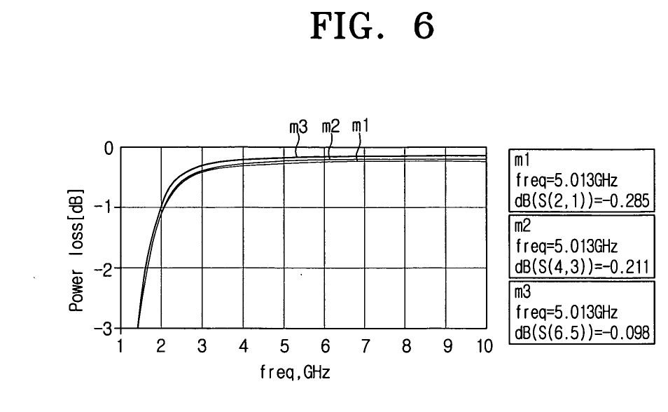

FIG. 6 is a graph illustrating power loss according to the exemplary embodiments of the present invention. Referring to FIG. 6, a graph m1 illustrates power loss of the conventional MIM capacitor having no ground shield layer, a graph m2 illustrates power loss of the MIM capacitor having the ground shield layer according to one of the exemplary embodiments of the present invention, and a graph m3 illustrates power loss of the MIM capacitor having a patterned result of the ground shield layer to optimize the capacitance Cox and the resistance Rsub. According to the graph m1, the power loss in the range of 5 GHz is −0.285 [dB]. According to the graph m2, in the case of the ground shield layer, it is to be noted that the power loss in the range of 5 GHz is reduced to −0.211 [dB]. According to the graph m3, in the case of the patterned ground shield layer, it is to be noted that the power loss in the range of 5 GHz is adjusted to −0.098 [dB]. Therefore, power loss is greatly reduced when the ground shield layer is used.

As described above, in the present invention, it is possible to manufacture the MIM capacitor that can prevent signal loss and power loss due to the substrate using the ground shield layer. Also, it is possible to minimize signal loss and power loss caused by the substrate by patterning the ground shield layer to further control the capacitance and the resistance.

The foregoing embodiment and advantages are merely exemplary in nature and are not to be construed as limiting the present invention. The present teaching can be readily applied to other types of apparatuses. Also, the description of the exemplary embodiments of the present invention is intended to be illustrative, and therefore it does not limit the scope of the claims. Alternatives, modifications, and variations of the exemplary embodiments described herein will be readily apparent to those skilled in the art.

What is claimed is:

1. An MIM (Metal-Insulator-Metal) capacitor comprising:
a substrate;
a capacitor part comprising:
a bottom electrode;
a dielectric layer; and
a top electrode,
wherein the bottom electrode, the dielectric layer and the top electrode are laminated in order; and
a ground shield layer formed between the bottom electrode of the capacitor part and the substrate, wherein the ground shield layer is connected to a predetermined ground terminal.

2. The MIM capacitor as claimed in claim 1, further comprising an insulating layer deposited on the substrate and positioned between the substrate and the ground shield layer.

3. The MIM capacitor as claimed in claim 2, wherein the ground shield layer is made of a predetermined conductive material deposited on the insulating layer.

4. The MIM capacitor as claimed in claim 3, wherein the ground shield layer is patterned in a predetermined shape.

5. The MIM capacitor as claimed in claim 3, wherein the ground shield layer is made of either metal or polysilicon.

6. The MIM capacitor as claimed in claim 1, wherein the substrate is a P type silicon semiconductor substrate.

7. The MIM capacitor as claimed in claim 6, wherein the ground shield layer is made of an N type doped layer formed in one region on the substrate.

8. The MIM capacitor as claimed in claim 2, further comprising a second insulating layer which is positioned between the ground shield layer and the bottom electrode of the capacitor part.
